(19) United States
(12) Patent Application Publication
(10) Pub. No.: US 2004/0159283 A1
(43) Pub. Date: Aug. 19, 2004

(54) Method for forming multilayer thin film and apparatus thereof

(76) Inventors: Jinpei Harada, Tokyo (JP); Atsushi Onoma, Kanagawa (JP); Yukihiro Kawai, Shizuoka (JP)

Correspondence Address: NIXON PEABODY, LLP, 401 9TH STREET, NW, SUITE 900, WASINGTON, DC, 20004-2128, US

(21) Appl. No.: 10/450,607

(22) PCT Filed: May 15, 2002
(86) PCT No.: PCT/JP02/04692

(30) Foreign Application Priority Data
Oct. 17, 2001 (JP) 2001-318913

(51) Int. Cl. C23C 16/00; B05D 5/06; B05D 1/36

(52) U.S. Cl. 118/712; 427/8; 427/162; 427/402

(57) ABSTRACT

The invention relates to a method for forming a multilayer thin film and an apparatus thereof, which are able to form a thin layer at an accuracy of 0.5 nanometers or less on at least a specified layer during formation on a substrate (W) and to increase the yield of multilayer thin film products. X-rays are irradiated from X-ray irradiating means (6) onto the surface of a multilayer thin film during formation on the substrate (W) at angles from 0 to 1.5 degrees, and the obtained reflected X-rays are measured by X-ray measuring means (7) while varying the incident angle θ, wherein reflectivity curve depicting the intensities of the reflected X-rays are obtained with respect to the scattering angle 2θ, and the reflectivity curve, whose scattering angles exist in a range of 0 to 1 degree, of the reflectivity curve is analyzed. Herein, the thickness of a thin layer during formation is estimated, and a thin layer having a prescribed thickness is formed by controlling the thickness of a layer during formation, utilizing the estimated results.

### TECHNICAL FIELD

The present invention relates to a method for forming a multilayer thin film and an apparatus for forming the same, and in detail a method and an apparatus for forming a multilayer thin film such as an optical multilayer thin film, etc., by measuring the thickness of a thin layer during formation of a thin layer on a substrate, and securing a prescribed layer thickness by controlling a shutter for opening and closing thereof on the basis of the thickness of the thin layer.

### PRIOR ARTS

A number of components in which thin layers are multilayer on a substrate as shown in FIG. 5 have been used in recent electronic devices and optical communications devices, etc. These components are a semiconductor element, a band-pass wave filter for an optical communications device, quartz oscillator substrate, etc.

High performance and high quality have been recently demanded with regard to components having a multilayer thin film formed thereon, and a necessity for enhancing the accuracy of thin layers (in respective layers) has increased.

Conventionally, in a case where a thin film is formed on a substrate, the thickness of thin film has been measured by the following methods:

(1) Method in which a monitor substrate is installed in the vicinity of a substrate on which thin films are formed, light is irradiated from the surface or rear side of the monitor substrate, and the reflectivity or transmissivity is measured.

(2) Method in which a quartz oscillator is installed in the vicinity of a substrate on which thin film is formed, and inherent frequency is measured by utilizing different inherent frequencies on the basis of thickness of thin film adhered to the quartz oscillator.

(3) Method for concurrently utilizing methods (1) and (2).

However, in the respective methods described above, since the measurement accuracy of film thickness is at a several nm level, and the monitor substrate or quartz oscillator is installed at a position differing from that of a substrate on which thin film is formed, the thickness of a thin film deposited thereon is different from the thickness of a thin film deposited on the substrate on which multiplayer thin film is formed, wherein the measurement is not accurate.

Therefore, if a product having a multilayer thin film provided on a substrate is inspected in regard to its film thickness by X-ray thickness measuring device, the yield of products was only 15 to 30% in the case of a band-pass wave filter for optical communications devices.

Also, a method has been publicly known, in which the film thickness of the mixed thin film deposited on the surface of a moving tape is measured for composition by irradiating X-rays onto the mixed thin film, and measuring the fluorescent X-ray strength thereof (Japanese Unexamined Patent Publication No. 2000-230819).

However, since the method is only for measuring the thickness of a thin film formed on the surface of a moving tape, it does not compensate the thickness even if the measured result is different from a prescribed thickness (for example, where the film is thin), and since the fluorescent X-ray strength is measured, it is difficult to obtain a measurement result on an absolute scale with high accuracy.

Further, a method has been publicly known, in which X-rays are made incident onto the surface of a thin layer during formation, at angle from 0 to 1.5 degrees, the reflectivity curve of the X-rays reflected from the thin layer is measured, the thickness of the thin layer is estimated by analyzing the reflectivity curve, and the thickness of the thin layer during formation is controlled on the basis of the result thereof (Japanese Unexamined Patent Publication No. 2001-66398).

Since the method utilizes interference of waves by a difference in the path-length of X-rays having a wavelength of sub-nanometers, shorter than visible light scattered at different positions, the method is suitable for control the thickness on a nanometer level. Accordingly, the method has already become an indispensable means for evaluation of film thickness, density, roughness of the surface and interface boundary of semiconductor thin films.

However, since it is necessary that all thin film layers laminated on a substrate are analyzed if the method is utilized for controlling the layer thickness of a multilayer film, the analysis becomes very difficult, and it is practically impossible. Therefore, the method has not been utilized. Also, in a case of a multilayer film for an optical system, the total film thickness of which is 1 micron or so, accuracy obtained could not be secured even if the analysis performance was increased.

It is therefore an object of the invention to provide a method for forming a multilayer thin film and an apparatus thereof, which are able to increase the yield of multilayer thin film products by forming thin layer on a substrate with an accuracy of 0.5 nanometers or less in regard to the thickness of a specified thin layer at least during formation of a multiplayer thin film.

### DISCLOSURE OF THE INVENTION

In order to solve the above-described problems and shortcomings, the inventor et al. eagerly researched a method for increasing the yield of multilayer thin film products such as optical multilayer thin films and an apparatus thereof. The inventor et al. obtained the following findings, which are that if, instead of measurement by using a monitor film, direct measurement is carried out on the thickness of a thin layer during formation, it is possible to accurately measure the thickness of the thin layer; that if X-rays whose wavelength are shorter than the accuracy (nm or less) of a layer thickness required for the measurement is used, the accuracy becomes higher than that by a conventional optical method or a method (whose accuracy is several nms or so) using a quartz oscillator; that the film thickness is thin if the layer thickness, density and roughness of the surface and interface boundaries, etc., of only the extreme surface layer of a multilayer film is directly measured by using X-rays, wherein although penetration depths differs from each other depending on the wavelength of the X-rays used, and the density of the substance of thin layer when investigating the penetration depths of the X-rays in regard to the incident angles, the X-rays deeply penetrates in terms of exponential function if the incident angle exceeds the total reflection area, and the thickness of the layer at only the extreme surface during formation cannot be obtained; however, if the scattering angle is limited in a range of conditions by which the film thickness of several films on the surface can be measured altogether, so that it is possible to obtain the thickness of a film of respective layers; and that if reflectivity curve is analyzed, which exist in a range in which the scattering angle is from 0 to 1 degree, of the reflectivity curve depicting the intensities of reflected X-rays obtained by irradiating X-rays so as to skim over the surface of a multilayer film during formation, that is, irradiating the X-rays at an angle from 0 to 1.5 degrees, it is possible to obtain the film thickness of respective thin films of several layers on the surface, density thereof, and roughness of the surface and interface boundaries.

The present invention was developed on the basis of the above-described findings.

That is, a method for forming a multilayer thin film according to the invention includes the steps of: measuring the reflected X-rays obtained by irradiating X-rays onto the surface of a multilayer film during formation on a substrate at an angle from 0 to 1.5 degrees, usually, 0 to 1 degree, by varying the incident angle θ; obtaining reflectivity curve depicting the intensities of the reflected X-rays with respect to the scattering angle 2θ; and analyzing the reflectivity curve, existing in a range of the reflectivity curve from 0 to 1 degree, wherein the thickness of a thin layer during formation is calculated, and a thin film of a prescribed thickness is formed by controlling the thickness of the layer during formation utilizing the result.

In addition, a method for forming a multilayer thin film includes the steps of: measuring the reflected X-rays obtained by irradiating X-rays onto the surface of a multilayer film during formation on a substrate at an angle from 0 to 1.5 degrees, usually, 0 to 1 degree, by varying the incident angle θ; obtaining reflectivity curve depicting the intensities of the reflected X-rays with respect to the scattering angle 2θ; and analyzing the reflectivity curve, existing in a range in which the scattering angle is from 0 to 1 degree, of the reflectivity curve; wherein the thickness of a thin film during formation is calculated, the calculated thickness of a thin film is outputted by display means or a printer, etc., as necessary, and a thin film of a prescribed thickness is formed by controlling opening and closing of a shutter or an amount of evaporation from an evaporation source, or the opening and closing thereof and the amount of evaporation from the evaporation source on the basis of the calculated result.

An apparatus for forming a multilayer thin film includes: a vacuum chamber composed so as to attach a substrate for laminating thin films in the upper part thereof; an evaporation source installed in the above-described vacuum chamber; a shutter provided between the above-described evaporation source and the above-described substrate; means for irradiating X-rays onto the surface of a multilayer thin film during formation, at an angle from 0 to 1.5 degrees; means for measuring the reflected X-rays; and means for calculating the thickness of a thin film during formation, by analyzing the reflectivity curve, whose scattering angle is in a range of 0 to 1 degree, of the reflectivity curve of data measured by the X-rays measuring means, and controlling the opening and closing of the above-described shutter or amount of evaporation from the evaporation source, or the opening and closing of the above-described shutter and amount of evaporation from the above-described evaporation source on the basis of the calculated result.

In addition, an apparatus for forming a multilayer thin film includes: a vacuum chamber composed so as to attach a substrate for laminating thin layers in the upper part thereof; an evaporation source installed in the above-described vacuum chamber; a shutter provided between the above-described evaporation source and the above-described substrate; means for irradiating X-rays onto the surface of a multilayer thin film during formation, at angle from 0 to 1.5 degrees; means for measuring the reflected X-rays; means for estimating the thickness of a thin layer during formation, by analyzing the reflectivity curve, whose scattering angle is in a range of 0 to 1 degree, of the reflectivity curve of data measured by the X-ray measuring means, and controlling the opening and closing of the above-described shutter or amount of evaporation from the evaporation source, or the opening and closing of the above-described shutter and amount of evaporation from the above-described evaporation source on the basis of the estimated result; means for displaying the thickness of a thin layer, which is obtained by the above-described calculating and controlling means; and a printer for printing out the thickness of the thin layer.

Further, “multilayer” in the method for forming a multilayer thin film according to the invention means three or more layers.

The method for forming a multilayer thin film and apparatus thereof according to the invention directly measures the thickness of a film at least at a specified layer during formation, and the reflected X-rays, which are obtained by irradiation of X-rays onto the surface thereof at an angle from 0 to 1.5 degrees by varying the incident angle θ, obtain reflectivity curve depicting the intensities of the reflected X-rays in regard to a scattering angle 2θ, and analyzes the reflectivity curve, for which the scattering angle exists in a range of 0 to 1 degree, of the reflectivity curve. Therefore, the method and apparatus are able to accurately measure the thickness, density, etc., of thin layer during formation.

Since a thin layer is formed while measuring the thickness thereof during formation, it is possible to accurately form the film thickness at a prescribed thickness.

### BRIEF DESCRIPTION OF THE DRAWINGS

FIG. 1 shows the reflectivity curve from a multilayer film (TiO₂/SiO₂/TiO₂/glass substrate), in which three thin films are laminated on a glass substrate, at a scattering angle of 0.3 through 1.0 degree, and the results of analysis.

FIG. 2 shows the reflectivity curve from a multilayer film (SiO₂/TiO₂/SiO₂/TiO₂/glass substrate), in which four thin films are laminated on a glass substrate, at a scattering angle of 0.3 through 1.0 degree, and the results of analysis.

FIG. 3 shows the reflectivity curve from a multilayer film (TiO₂/SiO₂/TiO₂/SiO₂/TiO₂/glass substrate), in which five thin films are laminated on a glass substrate, at a scattering angle of 0.3 through 1.0 degree, and the results of analysis.

FIG. 4 is a roughly sectional view of one embodiment of a multilayer thin film forming apparatus according to the invention.

FIG. 5 is a sectional view showing one embodiment of a multilayer thin film that is produced by the method for forming a multilayer thin film and apparatus thereof according to the invention.

### BEST MODE FOR CARRYING OUT THE INVENTION

Hereinafter, a detailed description is given of a method for forming a multilayer thin film and apparatus thereof according to the invention with reference to the accompanying drawings.

First, a description is given of the method for forming a multilayer thin film according to the invention.

In the method for forming a multilayer thin film according to the invention, the reflected X-rays obtained by irradiating X-rays onto the surface of a multilayer film during formation on a substrate at an angle from 0 to 1.5 degrees, is measured by varying the incident angle θ; reflectivity curve depicting the intensities of the reflected X-rays are obtained with respect to the scattering angle 2θ; and the reflectivity curve is analyzed, which exists in a range in which the scattering angle is from 0 to 1 degree, of the reflectivity curve; wherein the thickness of a thin film during formation is calculated, the calculated thickness of a thin film is outputted by display means and/or a printer, etc., as necessary, utilizing the calculated results, and a thin film of a prescribed thickness is formed by controlling opening and closing of a shutter or an amount of evaporation from an evaporation source, or the opening and closing thereof and the amount of evaporation from the evaporation source on the basis of the calculated result. Herein, a thin film on the above-described substrate during formation is a thin film produced by vacuum evaporation.

A method for measuring the thickness of a thin film during formation, by measuring the X-rays reflected by irradiating X-rays in the thin film during formation on a substrate, in the above-described method for forming a multilayer thin film according to the invention (which is concurrently able to measure the density of a thin film, roughness of the surface and interface boundaries thereof) irradiates X-rays, which are radiated from X-ray measuring means 6 consisting of a X-ray generating source and a monochromat or for monochromating and paralleling the X-rays, onto the surface of a thin film during formation, at an angle from 0 to 1.5 degrees, measures the reflected X-rays by the X-ray measuring means 7 in accordance with a publicly known measuring method, inputs the results into the calculating and controlling means 8, obtains reflectivity curve depicting the intensities of the reflected X-rays with respect to the scattering angle, and obtains the thickness of the thin film, which is obtained by analyzing the reflectivity curve, existing in a range whose scattering angle is from 0 to 1 degree, of the reflectivity curve.

In the above-described method for forming a multilayer thin film according to the invention, the reason why X-rays are irradiated onto the surface of a multilayer film during formation, at an angle from 0 to 1.5 degrees, usually 0 to 1 degree is that reflected X-rays which are reflected from several layers on the surface are obtained, and if the angle exceeds 1.5 degrees, usually 1 degree, the irradiated X-rays excessively deeply penetrate into the multilayer thin film, wherein since it becomes necessary to analyze more layers, the analysis becomes difficult.

Further, the reason why the reflectivity curve, whose scattering angle is in a range of 0 to 1 degree is analyzed is that the range covers the X-rays reflected from a few layers on the surface. If the scattering angle exceeds 1 degree, since the X-rays reflected from several layers in deep region are included, wherein since it becomes necessary to analyze each layer of such multilayer thin films, respectively, the analysis becomes difficult.

A method for forming a layer with a prescribed thickness by using the thickness of the layer obtained by the above-described calculating means, etc., in the multilayer thin film forming method according to the invention forms a thin layer by controlling the opening and closing of a shutter and the amount of evaporation from the evaporation source utilizing the thickness of the above-described thin layer. Also, the displaying means 18 displays the layer thickness, and/or the printer prints it out.

In the multilayer thin film forming method according to the invention, a method for controlling the opening and closing of the shutter and/or the amount of evaporation from the evaporation source on the basis of the thickness of the thin layer obtained by the above-described calculating means compares the thickness of a thin layer, which is obtained by the calculating and controlling means 8, with the final thickness (the layer thickness of product) of the layer during formation, which is inputted in advance in the calculating and controlling means 8, and, on the basis of the results, controls the opening and closing of the shutter and/or the amount of evaporation, for example, controls the irradiation of an electron beam from an electronic gun 16.

Further, a case where a prescribed thickness is obtained by controlling the thickness of only a specified layer during formation is included in the multilayer thin film forming method according to the invention. This is because there are cases where accuracy in thickness is required to only a specified layer in an optical multilayer thin film.

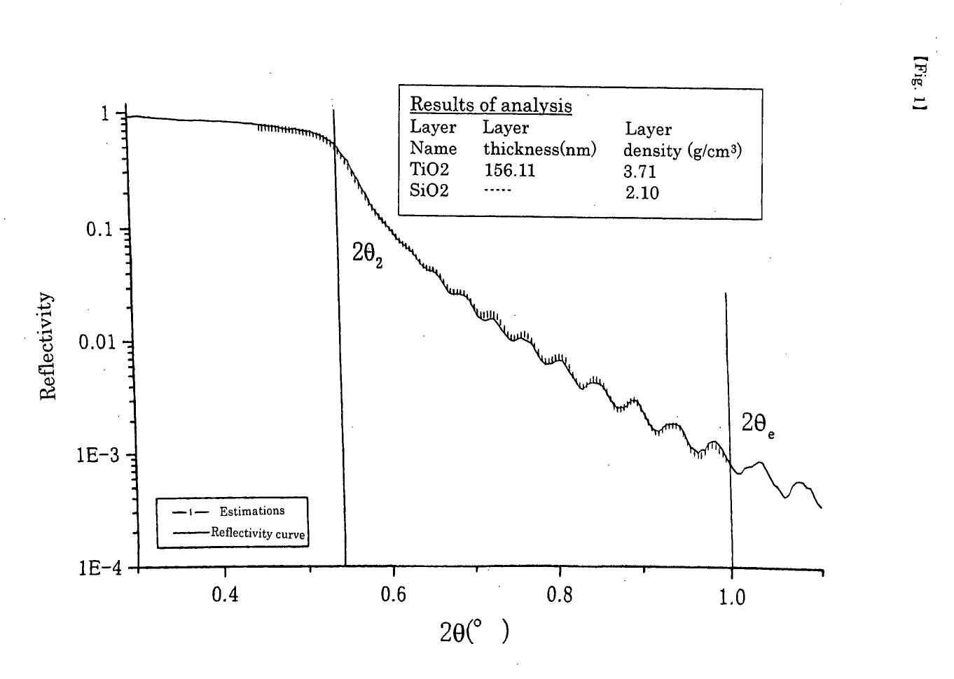

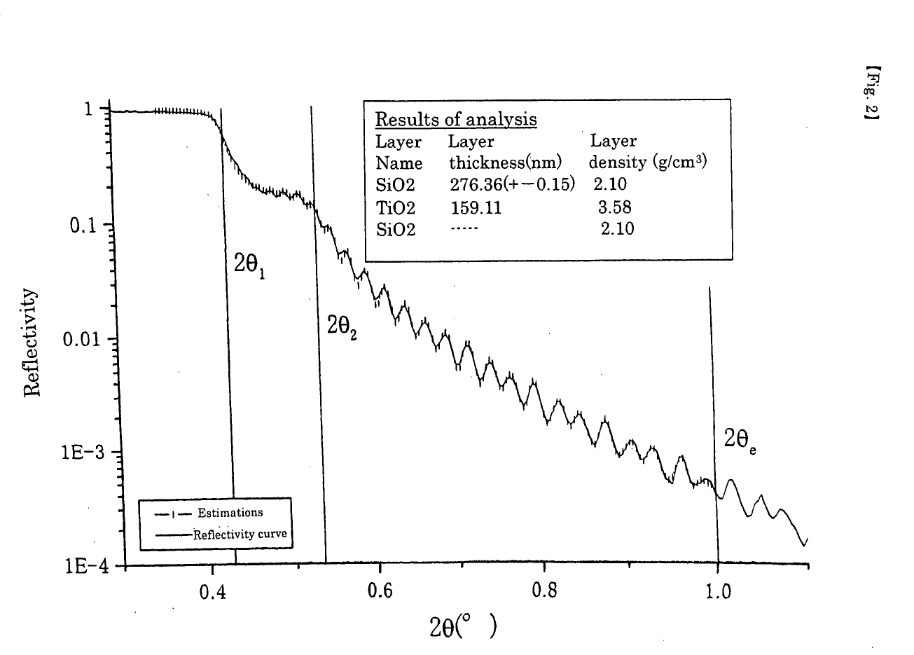

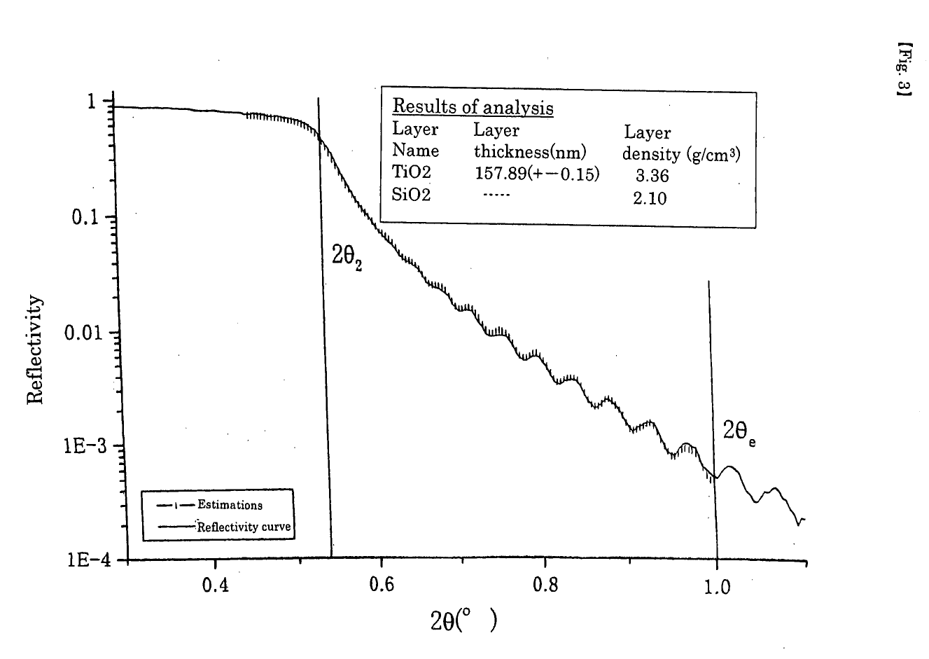

Next, a description is given of a detailed example of a method (which is able to concurrently measure the density and thikness of a layer and roughness of the surface and interface boundaries thereof) for measuring the thickness of a thin layer in the multilayer thin film forming method according to the invention. FIG. 1, FIG. 2 and FIG. 3 show the reflectivity curve measured at a scattering angle of 0.3 through 1.0 degree in regard to a multilayer thin film in which three layers of thin film (TiO₂/SiO₂/TiO₂/glass substrate), four layers of thin film (SiO₂/TiO₂/SiO₂/TiO₂/glass substrate), and five layers of thin film (TiO₂/SiO₂/TiO₂/SiO₂/TiO₂/glass substrate) are laminated on a glass substrate, respectively, and also show the results of analysis. With respect to the three layered and five layered thin films, the thickness of a TiO₂ layer on the extreme surface can be obtained by analyzing the two-layered thin films on the surface, and since, with respect to the four-layered thin film, the X-ray absorption is slight in the SiO₂ layer existing on the extreme surface, it is possible to obtain the thickness of the SiO₂ layer on the extreme surface by analyzing the three-layered thin film on the surface. In any case, only a low reflection angle region in which 2θ is up to 2θₑ (in this case, =1 degree) including the total reflection area of the X-rays are required as the range of reflectivity curve necessary for the analysis. Also, it can be judged, on the basis of a difference in appearance of the critical angle 2θ₂ of the total reflection and from FIG. 1 and FIG. 3 or FIG. 1 and FIG. 2, whether or not the layer on the extreme surface is TiO₂ layer or SiO₂ layer, and furthermore the density of the layer can be obtained. In addition, the method has a feature by which an absolute value can be obtained as the layer thickness.

A construction of a multilayer film has a characteristic feature, wherein, even in a case where many layers are laminated, and for example, the total film thickness remarkably exceeds 1 micron, or where it is unknown what kind of material is used for a layer coming thereunder and how the under layers are composed, the thickness of a layer on the extreme surface can be accurately measured by analyzing the two or three layers on the surface if the reflection curve whose scattering angle is from 0 to 1 degree is found.

In the case of an optical multilayer thin film, an important point in a thin layer of at least a specified layer is a layer formation volume (per unit area) consisting of the thickness and density of a thin layer). However, since the density of the thin layer is made constant if the chemical composition of the thin layer is the same and the multilayer thin film forming apparatus used is the same, it is not necessary to control the layer thickness in accordance with the result of measurement of the thin film during formation if the thickness of the thin layer is determined (the thickness is thickened if the density is thin), taking the density of the thin film into consideration in advance.

Since, in the method for forming a multilayer thin film according to the invention, the method for measuring the thickness of a thin layer is able to measure the density of the thin layer at the same time, the density obtained can be utilized to determine the thickness of the above-described thin layer.

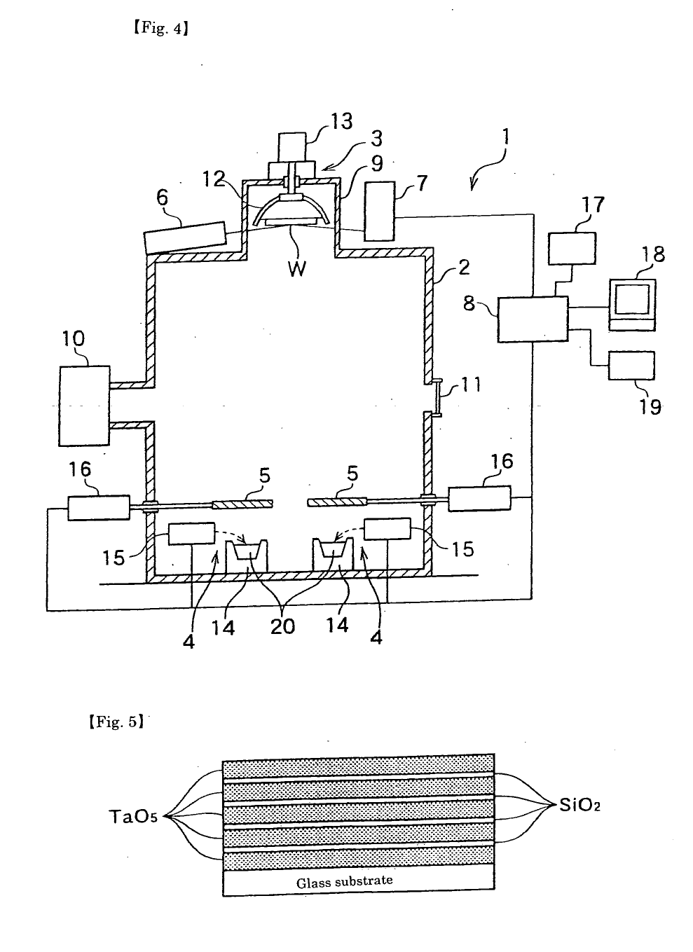

Next, a description is given of one embodiment of an apparatus for forming a multilayer thin film according to the invention with reference to FIG. 4.

A multilayer thin film forming apparatus 1 according to one embodiment of the invention comprises a vacuum chamber 2 for vacuum evaporation, a substrate attaching unit 3 for attaching a substrate W, an evaporation source 4, a shutter 5, means 6 for irradiating X-rays onto a thin layer during formation, means 7 for measuring the X-rays, which measures the intensity of the reflected X-rays, and means for obtaining the thickness and density of a thin layer by analyzing reflectivity curve measured by the X-ray measuring means, and calculating and controlling the opening and closing of the shutter and/or the amount of evaporation on the basis of the obtained thickness of the thin layer.

The above-described vacuum chamber 2 is provided, on its upper part, with a protrusion portion 9 for measuring the thickness of the thin film by irradiating X-rays onto the thin layer during formation and for securing the substrate attaching unit 3 for attaching the substrate W, and an exhaust system 10 is connected thereto, which makes the inside thereof vacuum. Further, the vacuum chamber 2 is provided with a observation window 11, which can be partially opened and closed to attach a substrate W, take out the substrate W having a multilayer thin film formed thereon, and carry out maintenance. Also, the evaporation source 4 and shutter 5 are placed therein.

In addition, the substrate attaching unit 3 for attaching a substrate W, which is provided inside and outside the protrusion portion 9 of the above-described vacuum chamber 2 includes a substrate attaching fixture 12 for attaching a substrate W and an attaching fixture turning unit 13 consisting of a motor for rotating the fixture 12 and speed change gears, etc.

The above-described evaporation source 4 evaporates an evaporation material 20 for forming a thin film, which includes a crucible 14 in which a melted evaporation material 20 is placed, and an electronic gun 1.5 for heating the evaporation material 20. In the present embodiment, these components are provided two by two, which are able to form two types of thin films. The electronic gun 1.5 is controlled to be turned ON and OFF on the basis of signals outputted from the calculating and controlling means 8 described below.

The above-described shutter 5 interrupts the evaporation material 20 which may be scattered toward the substrate W, and the shutter 5 is provided with a shutter drive unit 16 that drives the shutter 5. The shutter 5 is controlled to be opened and closed by the shutter drive unit 16 on the basis of signals outputted from the calculating and controlling means 8 described below.

The X-ray irradiating means 6 for irradiating X-rays onto a thin layer during formation irradiates X-rays onto a thin layer during formation on the substrate W, and the X-ray measuring means 7 for measuring the intensity of the reflected X-rays measure the intensity of the X-rays reflected with respect to the scattering angle (which is the sum of two angles, that is 2θ: the angle θ by which the X-ray irradiating means 6 is rotated and the angle θ by which the X-ray measuring means 7 are rotated) Then, the intensity is transferred to and inputted in the calculating and controlling means 8.

Of these, the X-ray irradiating means 6 includes X-ray generating source, a monochromator portion for converting the X-rays radiated from the X-ray generating source to a monochromatic parallel X-rays, and a collimator portion for collimation. And, the means 6 is attached so as to rotate by at least 1.5 degrees upward and downward from the horizontal level so that the direction of incident X-rays can be varied. Since the X-ray measuring means 7 includes X-rays receiving slit and a detector, and measures the intensity of the X-rays reflected from the thin layer during formation with respect to a value 2θ, which is two times of the reflection angle θ, the means 7 is attached so as to control the rotation thereof by approximately 5 degrees upward and downward from the horizontal level so that the direction along which the X-rays are received is changed. Therefore, the means 7 measures the reflectivity curve expressing the reflection intensity with respect to a change in the scattering angle and successively inputs the data in the calculating and controlling means 8 described below.

The results measured by means of the X-ray measuring means 7 are transferred to and inputted in the calculating and controlling means 8 in which the data measured by the above-described X-ray measuring means 7 are inputted, thereby obtaining the reflectivity curve. The reflectivity curve is analyzed on the basis of an analysis expression prepared in advance, wherein the thickness and density of a thin layer are estimated, and are inputted in the displaying means 18 such as a CRT, and/or a printer 19 as an output.

In addition, the above-described calculated thickness is compared with the final thickness (the thickness of a product) of a thin layer during formation, which is inputted in advance from the inputting means 17, the data of the comparison results are inputted in the shutter drive unit 16 and/or the controlling means (not illustrated) of the electronic gun 1.5 as outputs from the calculating and controlling means 8, wherein the opening and closing of the shutter 5 and/or amount of evaporation from the evaporation source 4, that is, irradiation of electronic beams from the electronic gun 1.5 are controlled.

Next, a description is given of one example of the methods for using the above-described multilayer thin film forming apparatus according to the invention, using the example shown in FIG. 5.

First, data of the thickness of evaporation thin layer and X-rays reflectivity, which have been already prepared, regarding two types of evaporation materials to be prepared, that is, evaporation samples of TaO₅ and SiO₂, and the final thickness (thickness of a product) of respective thin films to be prepared are inputted by the inputting means 17 in the calculating and controlling means 18. After that, a substrate W for forming a multilayer thin film is attached to the substrate attaching fixture 12, the evaporation materials 20 are placed in the crucibles 14, and the vacuum chamber 2 is made vacuum by driving the exhaust system 10. On the other hand, TaO₅ of the two evaporation materials 20 is melted by irradiating an electronic beam by operating the electronic gun 1.5, wherein the material is evaporated and begins being evaporated on the substrate W.

Simultaneously, the X-ray irradiating means 6 and X-ray measuring means 7 are started, and the intensity of the reflected X-rays are measured. Data of the reflectivity curve obtained by the calculating and controlling means 8 are successively analyzed to estimate the thickness and density of a thin layer during formation, and are displayed in the displaying means 18 and/or printed out by the printer 19. Also, in the case where the thickness of the thin layer is compared with the final thickness and is not the final thickness, no signal is outputted from the calculating and controlling means 8 so that the evaporation is continued as it is. As the data measured by the X-ray irradiating means 6 and X-ray measuring means 7 become the final thickness, signals for controlling the opening and closing of the shutter 5 and/or amount of evaporation from the evaporation source 4 are outputted from the calculating and controlling means 8 and are inputted into the controlling means of the shutter drive unit 16 and electronic gun 1.5, wherein the shutter 5 is closed and the electronic gun 1.5 is turned off.

After that, an electronic beam is irradiated by starting another electronic gun 1.5, and the other SiO₂ of the evaporation material 20 is melted and evaporated, wherein evaporation is commenced on the thin layer of the TaO₅ on the substrate W. As the evaporation is commenced, the X-ray irradiating means 6 and X-ray measuring means 7 are actuated, and the above procedure is repeated, wherein a thin layer of SiO₂ having a prescribed thickness is formed.

Further, after that, a signal is outputted from the calculating and controlling means 8 and is inputted in the shutter drive unit 16 to open the shutter 5, wherein one electronic gun 1.5 is actuated to melt and evaporate one TaO₅ of the evaporation material 20. Then, evaporation thereof is commenced, and the above procedure is repeated, wherein a thin layer of TaO₅ having a prescribed thickness is formed. By repeating these procedures, a multilayer thin film is formed on the substrate.

### Industrial Applicability

Since the method for forming a multilayer thin film and apparatus thereof according to the invention is constructed as described above, the following excellent effects can be brought about.

(1) Since the thickness of a thin layer during formation is directly measured and successively measured by the X-ray measuring unit, it is possible to accurately measure the thickness of a thin layer during formation.

(2) Reflected X-rays obtained by irradiating the X-rays onto the surface of a thin layer during formation at angles from 0 to 1.5 degrees are measured by varying the incident angle θ, and reflectivity curve depicting the intensities of the reflected X-rays are obtained with respect to the scattering angle 2θ. And, since the reflectivity curve, whose scattering angle is in a range of 0 to 1 degree, of the reflectivity curve is analyzed, it is possible to accurately and easily measure the thickness and density of thin layer during formation.

(3) Since the opening and closing of the shutter and/or amount of evaporation from an evaporation source are controlled while measuring the thickness of thin layers during formation, it is possible to accurately form the thickness of thin layers at a prescribed thickness.

(4) Since X-rays are used, it accordingly becomes possible to simultaneously measure the surface roughness, crystallinity, etc., of thin layers.

What is claimed is:

1. A method for forming a multilayer thin film including the steps of:
measuring reflected X-rays obtained by irradiating X-rays onto the surface of a multilayer film during formation on a substrate at angles from 0 to 1.5 degrees by varying the incident angle θ;
obtaining reflectivity curve depicting the intensities of said reflected X-rays with respect to the scattering angle 2θ; and
analyzing the reflectivity curve, existing in a range in which the scattering angle is from 0 to 1 degree, of the reflectivity curve;
wherein the thickness of a thin layer during formation is calculated, and a thin layer of a prescribed thickness is formed by controlling the thickness of a thin layer during formation, utilizing said calculated result.

2. A method for forming a multilayer thin film including the steps of:
measuring reflected X-rays obtained by irradiating X-rays onto the surface of a multilayer film during formation on a substrate at angles from 0 to 1.5 degrees by varying the incident angle θ;
obtaining reflectivity curve depicting the intensities of said reflected X-rays with respect to the scattering angle 2θ; and
analyzing the reflectivity curve, existing in a range in which the scattering angle is from 0 to 1 degree, of the reflectivity curve;
wherein a thin layer having a prescribed thickness is formed by estimating the thickness of a thin layer during formation, and controlling the opening and closing of a shutter on the basis of the calculated result.

3. A method for forming a multilayer thin film including the steps of:
measuring reflected X-rays obtained by irradiating X-rays onto the surface of a multilayer film during formation on a substrate at angles from 0 to 1.5 degrees by varying the incident angle θ;
obtaining reflectivity curve depicting the intensities of the reflected X-rays with respect to the scattering angle 2θ; and
analyzing the reflectivity curve, existing in a range in which the scattering angle is from 0 to 1 degree, of the reflectivity curve;
wherein a thin layer having a prescribed thickness is formed by calculating the thickness of a thin layer during formation, and controlling the amount of evaporation from an evaporation source on the basis of said calculated result.

4. A method for forming a multilayer thin film including the steps of:
measuring reflected X-rays obtained by irradiating X-rays onto the surface of a multilayer film during formation on a substrate at angles from 0 to 1.5 degrees by varying the incident angle θ;
obtaining reflectivity curve depicting the intensities of the reflected X-rays with respect to the scattering angle 2θ; and
analyzing the reflectivity curve, existing in a range in which the scattering angle is from 0 to 1 degree, of the reflectivity curve;
wherein a thin layer having a prescribed thickness is formed by estimating the thickness of a thin film during formation, and controlling the opening and closing of a shutter and the amount of evaporation from an evaporation source on the basis of said estimated result.

5. An apparatus for forming a multilayer thin film including:
a vacuum chamber composed so as to attach a substrate for laminating thin layer to the upper part thereof;
an evaporation source installed in said vacuum chamber;
a shutter provided between said evaporation source and said substrate;
means for irradiating X-rays onto the surface of a multilayer thin film during formation, at angles from 0 to 1.5 degrees;
means for measuring said reflected X-rays and means for estimating the thickness of a thin film during formation, by analyzing the reflectivity curve, whose scattering angles are in a range of 0 to 1 degree, of the reflectivity curve of data measured by said X-ray measuring means, and controlling the opening and closing of said shutter on the basis of said calculated result.

6. An apparatus for forming a multilayer thin film including:
a vacuum chamber composed so as to attach a substrate for laminating thin layer to the upper part thereof;
an evaporation source installed in said vacuum chamber;
a shutter provided between said evaporation source and said substrate;
means for irradiating X-rays onto the surface of a multilayer thin film during formation, at angles from 0 to 1.5 degrees;
means for measuring said reflected X-rays; and
means for estimating the thickness of a thin film during formation, by analyzing the reflectivity curve, whose scattering angles are in a range from 0 to 1 degree, of the reflectivity curve of data measured by the X-ray measuring means, and controlling the amount of evaporation from the evaporation source on the basis of said calculated result.

7. An apparatus for forming a multilayer thin film including: a vacuum chamber composed so as to attach a substrate for laminating thin layer to the upper part thereof;
an evaporation source installed in said vacuum chamber;
a shutter provided between said evaporation source and said substrate;
means for irradiating X-rays onto the surface of a multilayer thin film during formation, at angles from 0 to 1.5 degrees;
means for measuring the reflected X-rays;
means for estimating the thickness of a thin film during formation, by analyzing the reflectivity curve, whose scattering angles are in a range of 0 to 1 degree, of the reflectivity curve of data measured by the X-ray measuring means, and controlling the opening and closing of said shutter and amount of evaporation from the evaporation source on the basis of said calculated result.

8. The apparatus for forming a multilayer thin film as set forth in any one of claims 5 through 7, further comprising one or both of the means for displaying the thickness of a thin layer, which is obtained by said estimating and controlling means and a printer for printing out said thickness of said thin layer.
